(19) United States
(12) Patent Application Publication
(10) Pub. No.: US 2025/0199955 A1
(43) Pub. Date: Jun. 19, 2025

(54) RANDOM-ACCESS MEMORY SCRUBBING

(71) Applicant: BAE SYSTEMS Information and Electronic Systems Integration Inc., Nashua, NH (US)

(72) Inventors: David D. Moser, Haymarket, VA (US); Daniel L. Stanley, Warrenton, VA (US); Gregory B. Brown, Alexandria, VA (US)

(73) Assignee: BAE SYSTEMS Information and Electronic Systems Integration Inc., Nashua, NH (US)

(21) Appl. No.: 18/538,482

(22) Filed: Dec. 13, 2023

(51) Int. Cl. G06F 12/02

(52) U.S. Cl. CPC G06F 12/0253

(57) ABSTRACT

A memory device includes a memory module having a plurality of memory cells, a read port, a write port, and an output port; a first multiplexer having a functional read input, a scrub read input, a scrub read enable input, and a read request output, the read request output coupled to the read port; a second multiplexer having a functional write input, a scrub write input, a scrub write enable input, and a write request output, the write request output coupled to the write port; and a logic circuit configured to scrub, via the scrub write input, at least one of the memory cells based on the scrub read input while the scrub read enable input and/or the scrub write enable input are asserted.

### FIELD OF DISCLOSURE

The present disclosure relates to computer memory devices, and more particularly, to scrubbing for random-access memory (RAM) devices.

### BACKGROUND

Random-access memory is a semiconductor-based type of non-persistent (volatile) data storage. Memory devices incorporating RAM, such as those deployed in mission critical applications, can be subject to a single-event upset (SEU) or single event error (SEE) in which impinging radiation (e.g., ions, electrons, photons, etc.) changes the state of a storage unit (e.g., one or more bits). In some instances, the SEU can cause data errors that adversely affect operation of the system using the memory device. Therefore, non-trivial issues remain with respect to maintaining the integrity of data stored on memory devices vulnerable to the effects of radiation.

### BRIEF DESCRIPTION OF THE DRAWINGS

FIG. 1 is a block diagram of a system with scrubbing for RAM, in accordance with an example of the present disclosure.

FIG. 2 is a block diagram of a portion of the system of FIG. 1, in accordance with an example of the present disclosure.

FIG. 3 is a block diagram of a RAM circuit of the system of FIG. 1, in accordance with an example of the present disclosure.

FIG. 4A is a block diagram of a logic circuit of the system of FIG. 1, in accordance with an example of the present disclosure.

FIG. 4B is a block diagram of a state machine implemented by the logic circuit of FIG. 4A.

FIG. 5 is a flow diagram of a scrubbing process for the RAM circuit of the system of FIG. 1, in accordance with an example of the present disclosure.

FIG. 6 is a block diagram of an output circuit of a memory of FIG. 2, in accordance with an example of the present disclosure.

FIG. 7 is a block diagram of a processing platform configured to provide a system with RAM scrubbing, in accordance with an example of the present disclosure.

Although the following detailed description refers to illustrative examples, many alternatives, modifications, and variations thereof will be apparent in light of this disclosure.

### DETAILED DESCRIPTION

Techniques are provided herein for scrubbing for memory devices, such as RAM device. According to an example, a memory device includes a random-access memory circuit having a plurality of memory cells, a read port, a write port, and an output port. The memory device further includes a first multiplexer having a functional read input, a scrub read input, a scrub read enable input, and a read request output, where the read request output is coupled to the read port. The memory device further includes a second multiplexer having a functional write input, a scrub write input, a scrub write enable input, and a write request output, where the write request output is coupled to the write port. The memory device further includes a logic circuit configured to scrub, via the scrub write input, at least one of the memory cells based on the scrub read input while the scrub read enable input and/or the scrub write enable input are asserted (e.g., the inputs are turned on or otherwise in a state representing an active state). Scrubbing occurs only while functional read and write operations are not occurring; that is, during non-functional memory cycles.

### Overview

Memory scrubbing is an error-correction technique used for mitigating the effects of a SEU. Memory scrubbing includes reading data from a storage unit (e.g., a memory location), validating the data, correcting any errors in the data, and writing the corrected data back to the same storage unit. As noted above, memory devices, particularly those deployed in high-orbit or other space applications, are subjected to elevated levels of radiation, which can significantly increase data errors. As memory circuits become smaller, a single bit can be flipped from zero to one or from one to zero by a low amount of radiation energy, thereby causing an un-commanded change of the data stored in the device. These errors, if left uncorrected, can render the memory device non-functional or cause other system errors or failures.

Radiation shielding can reduce the risk of a SEU but increases the complexity, weight, and cost of the system. Error correction coding (ECC) schemes have been used for correcting SEU data errors. However, existing ECC schemes require the register transfer logic (RTL) or other executable code of the system to be modified to incorporate memory scrubbing. Such modifications of the RTL are difficult to implement because they require fundamental changes in the coding scheme. For example, the RTL must be modified at the functional level to stall writes to the memory device while the memory is read and corrected, if necessary, to prevent inadvertently overwriting new data during the scrubbing process. However, introducing memory write stalls can interfere with normal operation and thus require extensive redesigns and testing of the RTL to validate operational requirements, which is expensive and time-consuming if even possible, especially when embedded in third-party products having stringent performance requirements.

To this end, and in accordance with an example of the present disclosure, a scrubbing technique for a memory device is disclosed. Memory scrubbing is embedded at the memory device (RAM) level (e.g., a circuit embedded on the memory die), which avoids modification of the RTL. Scrubbing is performed during non-functional cycles; that is, during cycles where no memory reads or writes are occurring in conjunction with normal (non-scrubbing) operations. Additionally, a rate at which the scrubbing occurs can be adjusted to suit a given application. For example, for storage units that are infrequently written (e.g., where a write operation occurs once every hour, day, month, year, etc.), the scrubbing rate can be set such that it occurs only during certain non-functional cycles rather than during all non-functional cycles. Numerous other embodiments and variations will be apparent.

### System Architecture

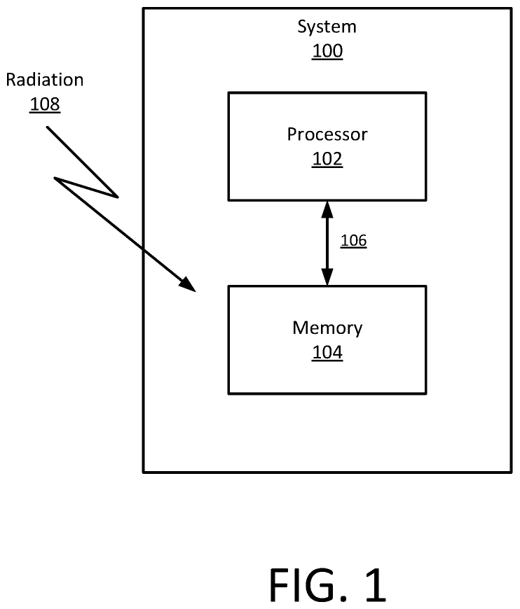

FIG. 1 is a block diagram of a system 100 with scrubbing for RAM, in accordance with an example of the present disclosure. The system 100 can be, for example, a system deployed in space, such as on a satellite, or in another environment with high levels of ionizing radiation, such as military or nuclear applications, sun flare events, and/or electromagnetic pulse (EMP) events. The system 100 further includes at least one processor and/or multiple core processors 102 operatively coupled to at least one memory 104 or other type of data storage device via a data communication bus 106. The memory 104 can include, for example, electronic computer memory (e.g., an integrated circuit with metal-oxide-semiconductor (MOS) memory cells) for storing data that can be read and modified by the processor 102.

As noted above, one or more individual cells within the memory 104 can be vulnerable to radiation 108. The system 100 is configured to detect and correct data errors within the memory 104, such as SEU errors caused by the radiation 108 impinging on the memory 104. Memory scrubbing logic is embedded in the memory 104, such as with logic-in-memory, system-on-chip, or a logic circuit that is embedded into the memory die or otherwise tightly integrated with the memory cells. Such embedded logic is configured to perform scrubbing operations during memory cycles where no data from the processor 102 is being written to the memory 104.

Data is retrieved from or written to individual cells within the memory 104 during a memory cycle of the system 100. Such memory cycles occur periodically as defined by a clock (e.g., every 50 nanoseconds) and are scheduled to permit sufficient time for data to be retrieved from or written to the memory 104. The length of each memory cycle depends on factors such as the speed of the processor 102, the speed of the data communication bus between the processor 102 and the memory 104, and the speed of the memory 104. For instance, the time needed to complete one memory cycle can include, at least, an amount of time for the system 100 to access and retrieve information from, or store to, the memory 104.

Each memory cycle used by the processor 102 to retrieve or write data is referred to as a functional memory cycle because the memory read/write operations are performed in service of one or more functions of the system 100. However, not every memory cycle is necessarily utilized for functional reads or writes. For example, some memory cycles may be unused when there are no pending read or write requests from the processor 102.

At least some of the unused, or non-functional, memory cycles can be instead used for performing scrubbing operations without interfering with functional memory operations or requiring modification of the RTL, such as described below. While non-functional memory cycles are not guaranteed to occur predictably, it may be unlikely that no non-functional memory cycles will occur over a given period of time, such as an hour, a day, a week, a month, etc., based on known operating parameters of the system 100. Thus, a sufficient number of non-functional memory cycles for effectively scrubbing the memory 104 can be expected to occur for a given application.

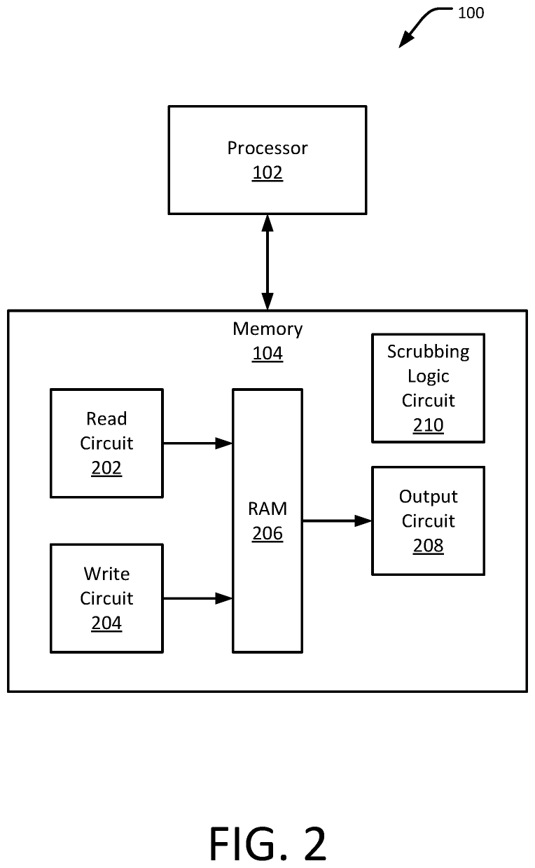

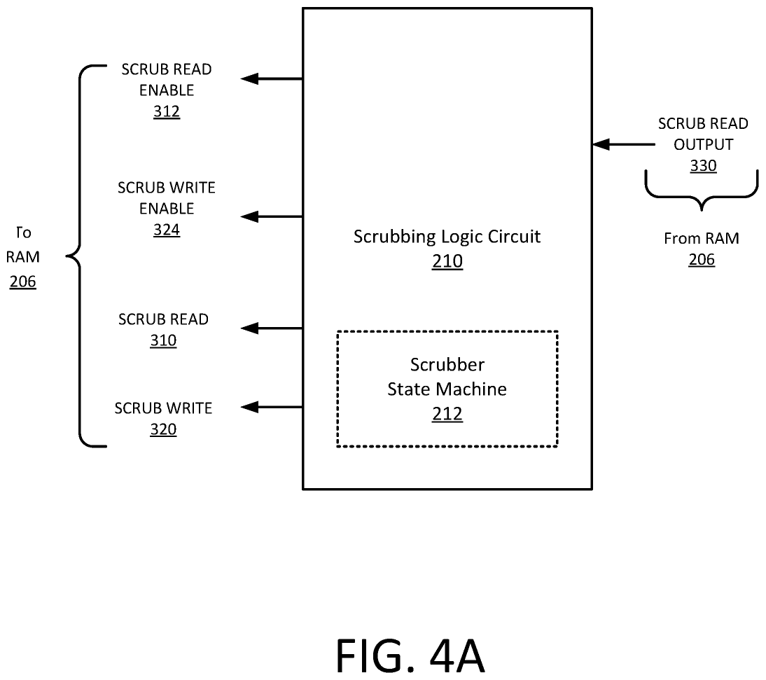

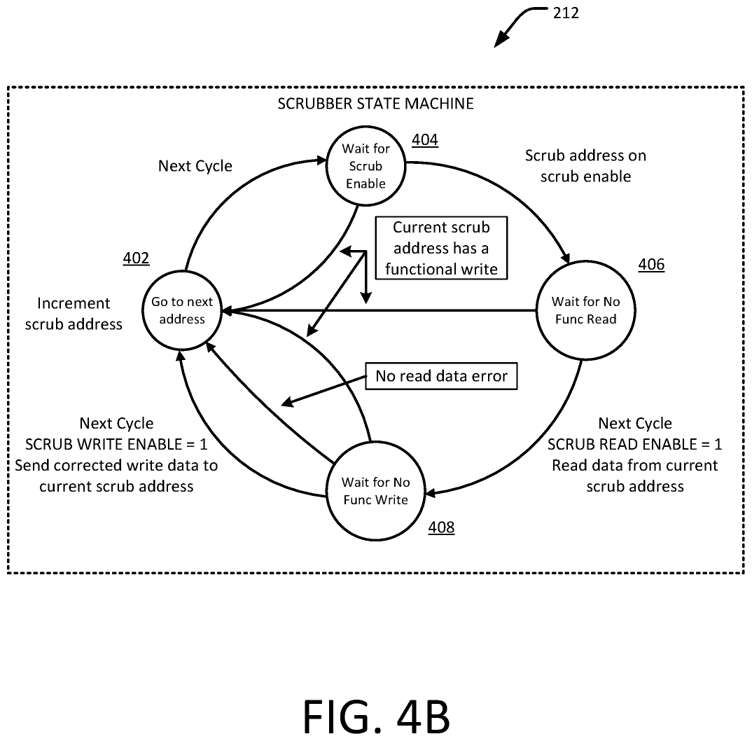

FIG. 2 is a block diagram of a portion of the system 100 of FIG. 1, in accordance with an example of the present disclosure. The system 100 includes the processor 102 and the memory 104, as shown in FIG. 1. The memory 104 further includes a read circuit 202, a write circuit 204, a RAM circuit 206, an output circuit 208, and a scrubbing logic circuit 210. The scrubbing logic circuit 210 is embedded in the memory 104, such as with logic-in-memory, system-on-chip, electrically programmable flash memory, or a logic circuit that is embedded into the memory die or otherwise tightly integrated with the memory cells. An example of the memory scrubbing logic provided by the scrubbing logic circuit 210 is the scrubbing process described with respect to FIG. 4.

The read circuit 202 is configured to provide a data read request to the RAM circuit 206. In response to the data read request, the RAM circuit 206 retrieves data and sends it to the output circuit 208. The data read request includes a memory cell address designating which memory cell or cells the RAM circuit 206 reads data out of. The data can include any number of bits as designated in the data read request. Further, the data read request can be a functional read or a scrub read. A functional read is a request to read data from the RAM circuit 206 for use by the processor 102 in service of non-scrubbing operations. A scrub read is a request to read data from the RAM circuit 206 for use by the scrubbing logic circuit 210 of the memory 104. The scrub read includes a request for performing a scrub operation on the data cell corresponding to the address specified in the data read request. A scrub operation is one in which data in the RAM circuit 206 is inspected and corrected for errors using an error correction scheme, such as from a redundant data source, a checksum, or other error correction data.

The write circuit 204 is configured to receive data from the processor 102 or other data source within the system 100, and to write the data to the RAM circuit 206. The data can include any number of bits and can be written to the memory cell or cells according to the memory cell address scheme. The write circuit 204 writes zero or more bits of data per memory cycle of the memory 104. For example, for each functional cycle of the memory 104, the write circuit 204 can write one or more bits of data to the RAM circuit 206 if the write circuit 204 receives data from the processor 102. If the write circuit 204 does not receive any data from the processor 102, then the memory cycle is considered a non-functional, or empty, cycle and the write circuit 204 does not write any data from the processor 102 to the RAM circuit 206. During a scrub operation, the write circuit 204 writes data from the scrubbing logic circuit 210 to the RAM circuit 206 for correcting any errors in the corresponding data cells.

The output circuit 208 is configured to receive data from the RAM circuit 206 and to send the data to the processor 102, the scrubbing logic circuit 210, or another component of the system 100 (such as a data communication interface).

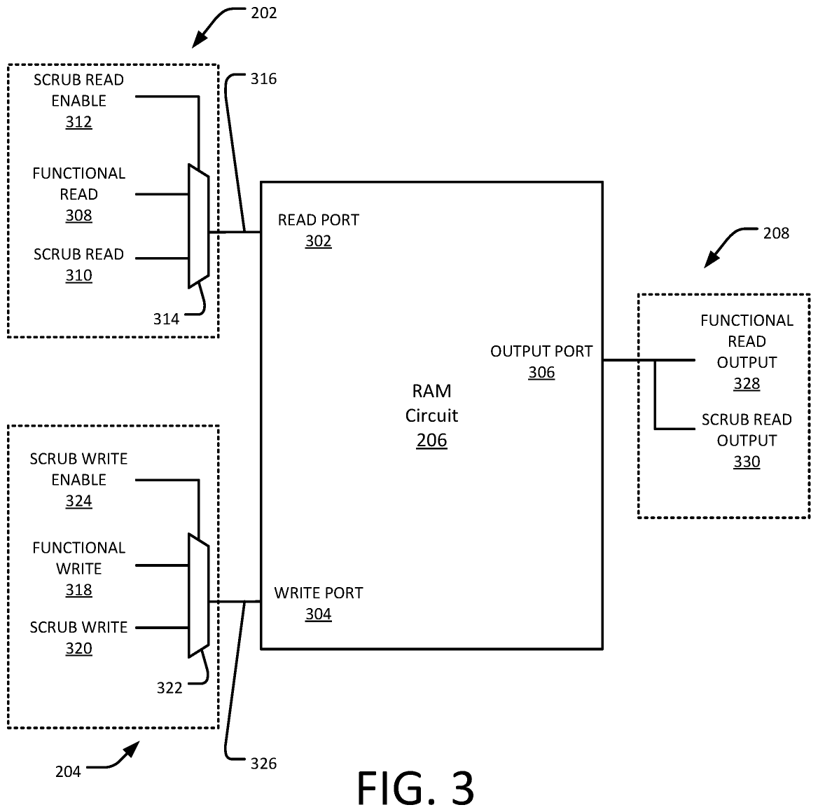

FIG. 3 is a block diagram of the RAM circuit 206 of the system 100 of FIG. 1, in accordance with an example of the present disclosure. The RAM circuit 206 includes a read port 302, a write port 304, and an output port 306. The RAM circuit 206 includes a plurality of memory cells, each of which can store at least one bit of data. The memory cells can be volatile or non-volatile, but in either case the memory cells are potentially susceptible to SEUs.

The read circuit 202 includes a first multiplexer 314, the write circuit 204 includes a second multiplexer 322, and the output circuit 208 includes a functional read output 328 and a scrub read output 330. The read port 302 is configured to receive a functional read request 308 from the processor 102 or a scrub read request 310 from the scrubbing logic circuit 210 via the first multiplexer 314. The first multiplexer 314 is controlled by a scrub read enable signal 312 from the scrubbing logic circuit 210. While the scrub read enable signal 312 is active, an output 316 of the first multiplexer 314 is the scrub read request 310; otherwise, the output 316 of the first multiplexer 314 is the functional read request 308. The scrub read enable signal 312 is inactive (e.g., low) during a functional memory cycle such that no scrub operations occur concurrently with functional read or write operations. The scrub read enable signal 312 is active (e.g., high) during a scrub operation, which occurs only while no functional read or write operation is occurring.

The write port 304 is configured to receive a functional write request 318 from the processor 102 or a scrub write request 320 from the scrubbing logic circuit 210 via the second multiplexer 322. The second multiplexer 322 is controlled by a scrub write enable signal 324 from the processor 102. While the scrub write enable signal 324 is active, an output 326 of the second multiplexer 322 is the functional write request 318; otherwise, the output 326 of the second multiplexer 322 is the scrub write request 320. The scrub write enable signal 324 can be active (e.g., high) during a scrubbing operation, that is, a non-functional memory cycle.

The functional read request 308 includes a request to read at least one bit of data out of the RAM circuit 206 for performing a functional memory operation of the system 100. The scrub read request 310 includes a request to read at least one bit of data out of the RAM circuit 306 for performing a scrub operation. The RAM circuit 206 outputs the data from the output port 306 as the functional read output 328 to the processor 102 in response to the functional read request 308, or as a scrub read output 330 to the scrubbing logic circuit 210 in response to the scrub read request 310.

Note that the RAM circuit 206 does not necessarily output data as a functional read output 328 or a scrub read output 330 on every memory cycle of the RAM circuit 206. For example, certain write cycles of the RAM circuit 206 cause data to be written into the RAM circuit 206 without any data output from the RAM circuit 206. Further, the RAM circuit 206 may not output any data during cycles where no functional read request 308 or scrub read request 310 are present.

In some examples, the scrub read request 310 is provided to the RAM circuit 206 at a pre-defined or adjustable frequency, as appropriate for a given application. For instance, scrub requests can be regulated (increased or decreased) based on a rate at which SEUs are expected to occur in a given application or environment of the system 100. For example, telemetry can be utilized to determine how often an SEU is expected to occur, and the scrub rate adjusted accordingly. SEUs caused by ionizing radiation may occur less frequently than by sun flares or non-destructive EMP activity. During periods of increased activity, the scrub rate can be increased and subsequently decreased after the increased activity subsides, based on the telemetry or other relevant data. It may not be necessary to perform a scrub operation more frequently than the expected SEU rate, although it will be understood that scrub operations can be performed during any non-functional memory cycle. Furthermore, it will be understood that functional memory write cycles also perform a scrub operation by virtue of writing new data to the RAM circuit 206 and overwriting any existing data.

The functional write request 318 includes a request to write at least one bit of data into the RAM circuit 206 for performing a functional memory operation of the system 100. The scrub write request 320 includes a request to write at least one bit of data into the RAM circuit 206 for performing a scrub operation.

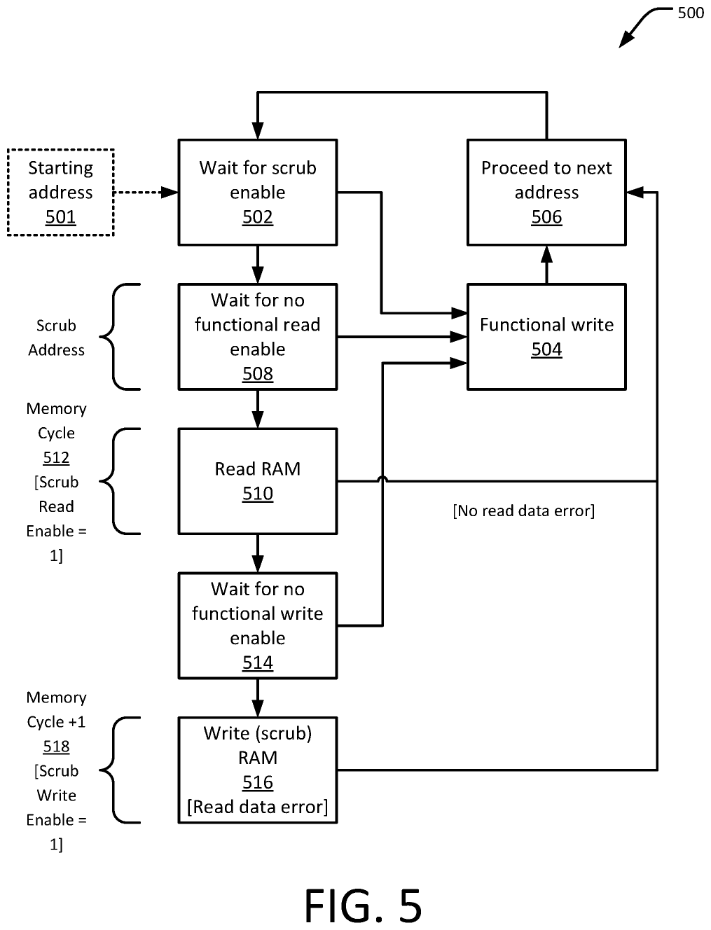

FIG. 4A is a block diagram of the scrubbing logic circuit 210, in accordance with an example of the present disclosure. The scrubbing logic circuit 210 provides, as an output to the RAM circuit 206, the scrub read enable signal 312, the scrub write enable signal 324, the scrub read request 310, and the scrub write request 320. The scrubbing logic circuit 210 receives, as an input from the RAM circuit 206, the scrub read output 330, which the RAM circuit 206 outputs in response to a scrub read request 310 while the scrub read enable signal 312 is asserted. The scrubbing logic circuit 210 is implemented in hardware, by a processor, and/or using programmable circuit embedded in the memory 104 and configured to implement a scrubbing state machine, such as shown in FIG. 4B, and/or carry out a scrubbing process, such as shown in FIG. 5. For example, the scrubbing logic circuit 210 can include an application-specific integrated circuit, a microprocessor, a programmable logic device, or other computer circuitry defined using a hardware description language (HDL) that describes, at a high level, the structure and behavior of the corresponding electronic or digital logic circuits that comprise the scrubbing logic circuit 210. In some examples, an HDL meeting the IEEE 1364 standard, such as Verilog, can be used to model the scrubbing logic circuit 210. Examples of a scrubbing process implemented by the scrubbing logic circuit 210 are described with respect to FIGS. 4B and 5.

### Scrubbing State Machine

FIG. 4B a block diagram of a state machine 212, which can be implemented by the scrubbing logic circuit 210, in accordance with an example of the present disclosure. At state 402, the state machine 212 sets the current scrubbing address to a starting address or increments the prior scrubbing address to the next address. The current scrubbing address is an address of a memory cell within the RAM 206 to be read and/or written during a non-functional memory cycle and during a scrubbing operation. On the next memory cycle, at state 404, the state machine 404 waits for a scrub enable to be enabled.

Scrubbing occurs only while the scrub enable is asserted. If a functional write operation is occurring at the current scrub address, the state machine 212 permits the functional write to occur and proceeds to state 402; no scrubbing occurs during the functional write operation. This is to prevent a scrub write from occurring after a functional write occurs and potentially overwriting refreshed data from the functional write.

However, if the functional write operation is not occurring at the current scrub address, then, at state 406, the state machine 212 waits until no functional read operation occurs. As above, if a functional write operation is occurring at the current scrub address, the state machine 212 permits the functional write to occur and proceeds to state 402. Otherwise, if no functional read operation is occurring, the state machine 212 asserts a SCRUB READ ENABLE signal to the RAM module 206 and reads data from the current scrub address in the RAM module 206. The data read from the current scrub address is evaluated for an error (e.g., using an error correction scheme such as Error Correction Coding or ECC).

At state 408, if there is no data error, the state machine 212 proceeds to state 402. Otherwise, the state machine waits until no functional write operation occurs. As above, if a functional write operation is occurring at the current scrub address, the state machine 212 permits the functional write to occur and proceeds to state 402. Otherwise, if no functional write operation is occurring, the state machine 212 asserts a SCRUB WRITE ENABLE signal to the RAM circuit 206 and sends the corrected data to the current scrub address in the RAM circuit 206. The state machine 212 then returns to state 402.

### Scrubbing Process

FIG. 5 is a flow diagram of a scrubbing process 500 for the memory 104, in accordance with an example of the present disclosure. The scrubbing process 500 can be implemented, for example, by a processor embedded in the memory 104 of the system 100. The scrubbing process 500 is executed using the scrubbing logic circuit 210 of the RAM circuit 206. In this manner, the functional code (e.g., RTL) executed by the processor 102 does not need to be modified. The scrubbing process 500 is performed in conjunction with the functional code of the system 100. The scrubbing process 500 does not interfere with the functional memory cycles but instead dovetails with them using any available non-functional memory cycles, if and when they occur. Furthermore, no scrubbing is performed on a given memory cell in the RAM circuit 206 while a functional write operation is in progress, since a functional write will overwrite any erroneous data caused by a SEU and refresh the state of the memory cell.

The scrubbing process 500 reads data from successive addresses within the RAM circuit 206, determines whether the data is corrupted (e.g., using an error correction scheme such as Error Correction Coding or ECC), and, if so, writes the corrected data back into the RAM circuit 206. The scrubbing process 500 can, in some examples, be scheduled to executed continuously, on a periodic basis, such as hourly, daily, weekly, etc., or under other conditions to manage power consumption.

The process 500 begins at a starting address 501, which can be any memory cell address within the RAM circuit 206, and iteratively proceeds through all of the addresses one-by-one. The process 500 includes waiting 502 for a scrub enable to be asserted (e.g., turned on). As noted above, the scrub enable can be asserted continuously, on a periodic basis, or under other conditions. However, scrubbing operations will not interfere with functional operations.

Scrubbing occurs only while the scrub enable is asserted. Furthermore, if the functional write request 318 is asserted, the process 500 includes permitting the functional write 504 to occur and proceeding 506 to the next memory address to wait 502 again for the scrub enable to be asserted; no scrubbing occurs during the functional write 504. This is to prevent a scrub write from occurring after a functional write occurs and potentially overwriting refreshed data from the functional write.

However, if the functional write request 318 is not asserted, then the process 500 includes waiting 508 for the scrub read enable signal 312 to be asserted, which occurs when no functional write operation 504 is occurring. If the scrub read enable signal 312 is asserted, the process 500 includes reading 510, during a non-functional memory cycle 512, data from the current address in the RAM circuit 206 based on the scrub read request 310. As above, however, if the functional write request 318 is asserted, the functional write 504 is permitted to occur and the process 500 proceeds 506 to the next memory address to wait 502 again for the scrub enable. If there is no read data error (that is, no error is detected at the current scrub address), then the process 500 proceeds 506 to the next address.

Otherwise, if a read data error is detected at the current scrub address, then the process 500 further includes waiting 514 for the scrub write enable signal 324 to be asserted, which occurs when no functional write operation 504 is occurring. If the scrub write enable signal 324 is asserted, the process 500 includes writing (scrubbing) 516, during a subsequent non-functional memory cycle 518, corrected data to the current address in the RAM circuit 206 based on the scrub write request 320. Note that corrected data is written at step 516 when needed to correct an error in the RAM circuit 206, as determined by comparing the data read at step 510 to the error correction scheme, such as ECC, or by using another suitable error detection or data validation process. The process 500 then proceeds 506 to the next memory address to wait 502 again for the scrub enable.

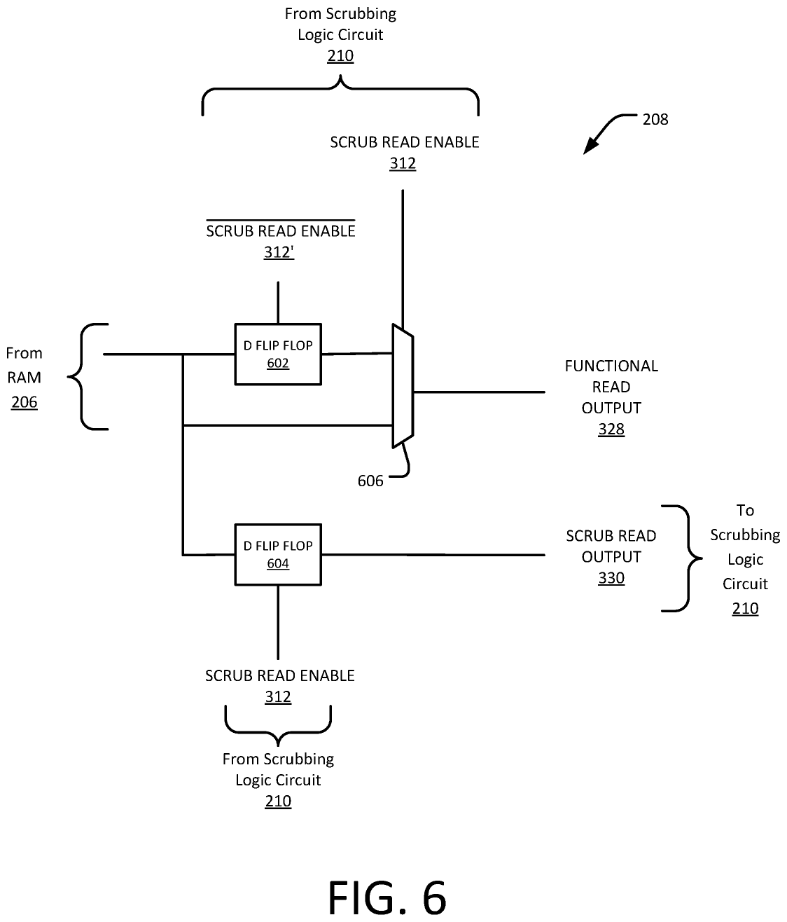

FIG. 6 is a block diagram of the output circuit 208 of the memory 104 of FIG. 2, in accordance with an example of the present disclosure. In some examples, the output circuit 208 includes a first delay (D) flip flop 602, a second D flip flop 604, and an output multiplexer 606 in series between the output port 306 of the RAM circuit 206 and the functional read output 328. The output multiplexer 606 is controlled via the scrub read enable signal 312 such that while the scrub read enable signal 312 is not asserted, the multiplexer passes the output port 306 straight through to the functional read output 328; otherwise, the D flip flop 602 is used to hold the last output of the RAM circuit 206 in a steady state until the output changes state (e.g., for use during automatic test pattern generation) and the multiplexer passes the output of the D flip flop 602 through to the functional read output 328. The D flip flop 602 is clocked via an inverse of the scrub read enable signal 312′ (e.g.,). \x \to (SCRUB READ ENABLE)

The scrub read output 330 to the scrubbing logic circuit 210 is clocked through the second D flip flop 604 when the scrub read enable signal 312 is asserted.

### Example System

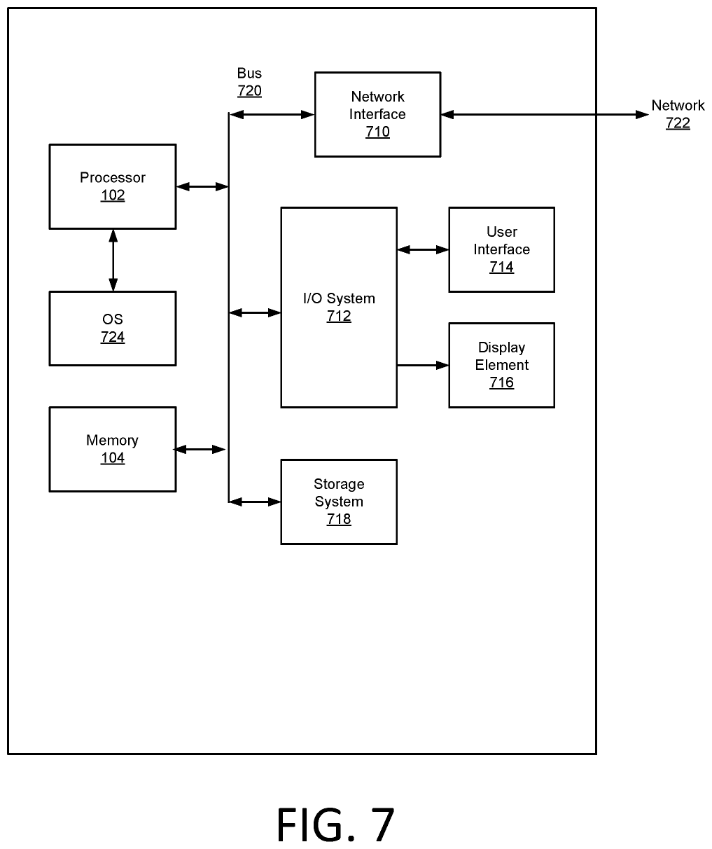

FIG. 7 is a block diagram of a processing platform 700 configured to provide a system with RAM scrubbing, in accordance with an example of the present disclosure. In some examples, the platform 700, or portions thereof, can be hosted on, or otherwise be incorporated into the electronic systems of a space-based or aerospace platform, including data communications systems, radar systems, computing systems, or embedded systems of any kind, where radiation can cause SEUs, although other applications (including terrestrial applications) will be apparent. The disclosed techniques can also be used to improve memory reliability in other platforms including data communication devices, personal computers, workstations, laptop computers, tablets, touchpads, portable computers, handheld computers, cellular telephones, smartphones, or messaging devices.

In an example, the platform 700 includes any combination of the processor 102, the memory 104, a network interface 710, an input/output (I/O) system 712, a user interface 714, a display element 716, and a storage system 718. For example, the platform includes the system 100 of FIG. 1, including the memory 104 with the scrubbing logic circuit 210 of FIG. 2. A bus and/or interconnect 720 is provided to allow for communication between the various components listed above and/or other components of the platform 700. The platform 700 can be coupled to a network 722 through the network interface 710 to allow for communications with other computing devices, platforms, devices to be controlled, and/or other resources. Other componentry and functionality not reflected in FIG. 7 will be apparent in light of this disclosure, and it will be appreciated that other examples are not limited to any particular hardware configuration.

The processor 102 can be any suitable processor, and can include one or more coprocessors or controllers, such as an audio processor, a graphics processing unit, or hardware accelerator, to assist in the execution of mission software and/or any control and processing operations associated with the platform 700. In some examples, the processor 102 is implemented as one or more processor cores. The processor core or cores can include any type of processor, such as, for example, a micro-processor, an embedded processor, a digital signal processor (DSP), a graphics processor (GPU), a network processor, a field programmable gate array (FPGA), or other computing or electronic device. The processor 102 can have multithreaded cores such that the processor 102 includes more than one hardware thread context or logical processor per core. In some examples, the processor 102 can be implemented as a complex instruction set computer (CISC) or a reduced instruction set computer (RISC) processor.

The memory 104 can be implemented using any suitable type of digital storage including, for example, a random-access memory (RAM). A random-access memory is any memory having storage locations, or cells, which can be read from and written to in any order. For example, the memory 104 can be implemented as a volatile memory device such as a RAM, dynamic RAM (DRAM), or static RAM (SRAM) device. The storage system 718 can be implemented as a non-volatile storage device such as a hard disk drive (HDD), a solid-state drive (SSD), a universal serial bus (USB) drive, an optical disk drive, tape drive, an internal storage device, an attached storage device, flash memory, battery backed-up synchronous DRAM (SDRAM), and/or a network accessible storage device.

The processor 102 can be configured to execute an Operating System (OS) 724, which can, for example, include any suitable operating system, such as Google Android (Google Inc., Mountain View, CA), Microsoft Windows (Microsoft Corp., Redmond, WA), macOS (Apple Inc., Cupertino, CA), Linux, or a real-time operating system (RTOS).

The network interface circuit 710 can be any network chip or chipset that provides wired and/or wireless connection between other components of the platform 700 and/or the network 722, thereby enabling the platform 700 to communicate with other local and/or remote computing systems, and/or other resources. Wired communication can include, for example, Ethernet. Wireless communication can include cellular communications including LTE (Long Term Evolution) and 5G, Wireless Fidelity (Wi-Fi), Bluetooth, and/or Near Field Communication (NFC). Wireless networks can include, for example, wireless local area networks, wireless personal area networks, wireless metropolitan area networks, cellular networks, and satellite networks.

The I/O system 712 can be configured to interface between various I/O devices and other components of platform 700. I/O devices can include, for example, the user interface 714 and the display element 716. The user interface 714 can include input/output devices such as a touchpad, keyboard, and mouse, etc., for example, to allow the user to interact with the platform 700 or components of the platform 700. The display element 716 can, for example, be configured to display information to a user. The I/O system 712 can include a graphics component configured render graphics on the display element 716. The graphics component can include, for example, a graphics processing unit or a visual processing unit. An analog or digital interface can be used to communicatively couple graphics subsystem and the display element. For example, the interface can include a high definition multimedia interface (HDMI), DisplayPort, wireless HDMI, and/or any other suitable interface using wireless high definition compliant techniques. In some examples, the graphics subsystem can be integrated into the processor 102 or another component (e.g., a graphics chipset) of the platform 700.

It will be appreciated that in some examples, the various components of the platform 700 can be combined or integrated in a system-on-a-chip (SoC) architecture. In some examples, the components can be hardware components, firmware components, software components or any suitable combination of hardware, firmware or software.

In some examples, the platform 700 can be implemented as a wireless system, a wired system, or a combination of both. When implemented as a wireless system, the platform 700 can include components and interfaces suitable for communicating over a wireless shared media, such as one or more antennae, transmitters, receivers, transceivers, amplifiers, filters, control logic, and so forth. An example of wireless shared media can include portions of a wireless spectrum, such as the radio frequency spectrum and so forth. When implemented as a wired system, the platform 700 can include components and interfaces suitable for communicating over wired communications media, such as input/output adapters, physical connectors to connect the input/output adaptor with a corresponding wired communications medium, a network interface card (NIC), disc controller, video controller, audio controller, and so forth. Examples of wired communications media can include a wire, cable metal leads, printed circuit board (PCB), backplane, switch fabric, semiconductor material, twisted pair wire, coaxial cable, fiber optics, and so forth.

Various examples of the present disclosure can be implemented using hardware elements, software elements, or a combination of both. Examples of hardware elements can include processors, microprocessors, circuits, circuit elements (for example, transistors, resistors, capacitors, inductors, and so forth), integrated circuits, ASICs, programmable logic devices, digital signal processors, FPGAs, logic gates, registers, semiconductor devices, chips, microchips, chipsets, and so forth. Examples of software can include software components, programs, applications, computer programs, application programs, system programs, machine programs, operating system software, middleware, firmware, software modules, routines, subroutines, functions, methods, procedures, software interfaces, application program interfaces, instruction sets, computing code, computer code, code segments, computer code segments, words, values, symbols, or any combination thereof. Determining whether an embodiment is implemented using hardware elements and/or software elements can vary in accordance with any number of factors, such as desired computational rate, power level, heat tolerances, processing cycle budget, input data rates, output data rates, memory resources, data bus speeds, and other design or performance constraints.

Some embodiments can be described using the expression “coupled” and “connected” along with their derivatives. These terms are not intended as synonyms for each other. For example, some embodiments can be described using the terms “connected” and/or “coupled” to indicate that two or more elements are in direct physical or electrical contact with each other. The term “coupled,” however, can also mean that two or more elements are not in direct contact with each other, but yet still cooperate or interact with each other.

Some examples disclosed herein can be implemented in various forms of hardware, software, firmware, and/or special purpose processors. For example, in one example, at least one non-transitory computer readable storage medium has instructions encoded thereon that, when executed by one or more processors, cause one or more of the methodologies disclosed herein to be implemented. The instructions can be encoded using a suitable programming language, such as C, C++, object oriented C, Java, JavaScript, Visual Basic .NET, Beginner's All-Purpose Symbolic Instruction Code (BASIC), or alternatively, using custom or proprietary instruction sets. The instructions can be provided in the form of one or more computer software applications and/or applets that are tangibly embodied on a memory device, and that can be executed by a computer having any suitable architecture. In one example, the system can be hosted on a given website and implemented, for example, using JavaScript or another suitable browser-based technology. For instance, in some examples, the system 100 can leverage processing resources provided by a remote computer system accessible via the network 722. The computer software applications disclosed herein can include any number of different modules, sub-modules, or other components of distinct functionality, and can provide information to, or receive information from, still other components. These modules can be used, for example, to communicate with input and/or output devices such as a display screen, a touch sensitive surface, a printer, and/or any other suitable device. Other componentry and functionality not reflected in the illustrations will be apparent in light of this disclosure, and it will be appreciated that other examples are not limited to any particular hardware or software configuration. Thus, in some examples, the platform 700 can include additional, fewer, or alternative subcomponents as those described above.

The non-transitory computer readable medium can include any suitable medium for storing digital information, such as a hard drive, a server, a flash memory, and/or random-access memory (RAM), or a combination of memories. In some examples, the components and/or modules disclosed herein can be implemented with hardware, including gate level logic such as a field-programmable gate array (FPGA), or alternatively, a purpose-built semiconductor such as an application-specific integrated circuit (ASIC). Still other examples can be implemented with a microcontroller having a number of input/output ports for receiving and outputting data, and a number of embedded routines for carrying out the various functionalities disclosed herein. It will be apparent that any suitable combination of hardware, software, and firmware can be used, and that other examples are not limited to any particular system architecture.

Some examples can be implemented, for example, using a machine readable medium or article that stores a set of instructions that, when executed by a machine, causes the machine to perform a method, process, and/or operations in accordance with the examples described herein. Such a machine can include, for example, any suitable processing platform, computing platform, computing device, processing device, computing system, processing system, computer, process, or the like, and can be implemented using any suitable combination of hardware and/or software. The machine readable medium or article can include, for example, any suitable type of memory unit, memory device, memory article, memory medium, storage device, storage article, storage medium, and/or storage unit, such as memory, removable or non-removable media, erasable or non-erasable media, writeable or rewriteable media, digital or analog media, hard disk, floppy disk, compact disk read only memory (CD-ROM), compact disk recordable (CD-R) memory, compact disk rewriteable (CD-RW) memory, optical disk, magnetic media, magneto-optical media, removable memory cards or disks, various types of digital versatile disk (DVD), a tape, a cassette, or the like. The instructions can include any suitable type of code, such as source code, compiled code, interpreted code, executable code, static code, dynamic code, encrypted code, and the like, implemented using any suitable high level, low level, object oriented, visual, compiled, and/or interpreted programming language.

Unless specifically stated otherwise, it will be appreciated that terms such as “processing,” “computing,” “calculating,” and “determining” refer to the action and/or process of a computer or computing system, or similar electronic computing device, that manipulates and/or transforms data represented as physical quantities (for example, electronic) within the registers and/or memory units of the computer system into other data similarly represented as physical entities within the registers, memory units, or other such information storage transmission or displays of the computer system.

The terms “circuit” or “circuitry” can include, for example, hardwired circuitry, programmable circuitry, such as computer processors comprising one or more individual instruction processing cores, state machine circuitry, and/or firmware that stores instructions executed by programmable circuitry. The circuitry can include a processor and/or controller configured to execute one or more instructions to perform one or more operations described herein. The instructions can be implemented as, for example, an application, software, firmware, etc., configured to cause the circuit or circuitry to perform any of the operations or functions described herein. Software can be implemented as a software package, code, instructions, instruction sets and/or data recorded on a computer-readable storage device. Software can be implemented to include any number of processes, and processes, in turn, can be implemented to include any number of threads, etc., in a hierarchical fashion. Firmware can be implemented as code, instructions or instruction sets and/or data that are hard-coded (e.g., nonvolatile) in memory devices. The circuit or circuitry can be implemented as part of a larger system, for example, an integrated circuit (IC), an application-specific integrated circuit (ASIC), a system-on-a-chip (SoC), desktop computers, laptop computers, tablet computers, servers, smartphones, etc. Other examples can be implemented as software executed by a programmable control device. In such cases, the terms “circuit” or “circuitry” are intended to include a combination of software and hardware such as a programmable control device or a processor capable of executing the software. As described herein, various examples can be implemented using hardware elements, software elements, or any combination thereof. Examples of hardware elements can include processors, microprocessors, circuits, circuit elements (e.g., transistors, resistors, capacitors, inductors, and so forth), integrated circuits, application specific integrated circuits (ASIC), programmable logic devices (PLD), digital signal processors (DSP), field programmable gate array (FPGA), logic gates, registers, semiconductor device, chips, microchips, and/or chip sets.

### Further Example Examples

The following examples pertain to further examples, from which numerous permutations and configurations will be apparent.

Example 1 provides a memory device comprising a random-access memory circuit having a plurality of memory cells, a read port, a write port, and an output port; a first multiplexer having a functional read input, a scrub read input, a scrub read enable input, and a read request output, the read request output coupled to the read port; a second multiplexer having a functional write input, a scrub write input, a scrub write enable input, and a write request output, the write request output coupled to the write port; and a logic circuit configured to scrub, via the scrub write input, at least one of the memory cells based on the scrub read input while the scrub read enable input and/or the scrub write enable input are asserted.

Example 2 includes the subject matter of Example 1, wherein the read port is configured to receive a read request signal, the write port configured to receive a write request signal, and the output port configured to output data from at least one of the memory cells responsive to the read request signal, and wherein the random-access memory circuit is configured to write data to at least one of the memory cells responsive to the write request signal.

Example 3 includes the subject matter of Example 2, wherein the read request signal is output on the read request output and includes one of the functional read input and the scrub read input based on the scrub read enable input.

Example 4 includes the subject matter of any one of Examples 2 and 3, wherein the write request signal is output on the write request output and includes one of the functional write input and the scrub write input based on the scrub write enable input.

Example 5 includes the subject matter of any one of Examples 1-4, wherein the logic circuit is configured to scrub at least one of the memory cells while a scrub enable signal is asserted.

Example 6 includes the subject matter of Example 5, wherein the logic circuit is configured to read data from at least one of the memory cells based on the scrub read input.

Example 7 includes the subject matter of Example 6, wherein the logic circuit is configured to write data to the at least one of the memory cells based on the scrub write input.

Example 8 includes the subject matter of any one of Examples 1-7, wherein the logic circuit is configured to permit a scrub write to occur based on the scrub write input while the scrub write enable input is asserted.

Example 9 includes the subject matter of any one of Examples 1-8, wherein the logic circuit is configured to permit a scrub read to occur based on the scrub read input while the scrub read enable input is asserted.

Example 10 provides a method of scrubbing a memory device, the method comprising reading data from at least one of a plurality of memory cells of the memory device; determining that the data is invalid; and writing, responsive to the determination, corrected data to the at least one of the memory cells while a scrub read enable input signal and/or a scrub write enable input signal are asserted.

Example 11 includes the subject matter of Example 10, wherein the reading occurs responsive to a scrub read input signal and a scrub enable signal.

Example 12 includes the subject matter of Example 11, wherein the writing occurs responsive to a scrub write input signal and the scrub enable signal.

Example 13 includes the subject matter of Example 12, further comprising controlling a first multiplexer based on the scrub read enable input signal, wherein the first multiplexer includes a functional read input configured to receive a functional read input signal, a scrub read input configured to receive the scrub read input signal, a scrub read enable input configured to receive the scrub read enable input signal, and a read request output, the read request output coupled to a read port of the memory and configured to provide, based on the controlling, one of the functional read input signal and the scrub write input signal to the read port.

Example 14 includes the subject matter of Example 13, further comprising controlling a second multiplexer based on the scrub write enable input signal, wherein the second multiplexer includes a functional write input configured to receive a functional write input signal, a scrub write input configured to receive the scrub write input signal, a scrub write enable input configured to receive the scrub write enable input signal, and a write request output, the write request output coupled to a write port of the memory and configured to provide, based on the controlling, one of the functional write input signal and the scrub write input signal to the write port.

Example 15 provides a memory module comprising a plurality of memory cells; a read port; a write port; an output port; and a logic circuit configured to scrub, during a time period when a scrub read enable input and/or a scrub write enable input are asserted, at least one of the memory cells via the read port, the write port, and the output port.

Example 16 includes the subject matter of Example 15, wherein the read port is coupled to a first multiplexer having a functional read input, a scrub read input, the scrub read enable input, and a read request output, the read request output coupled to the read port.

Example 17 includes the subject matter of Example 16, wherein the write port is coupled to a second multiplexer having a functional write input, a scrub write input, the scrub write enable input, and a write request output, the write request output coupled to the write port.

Example 18 includes the subject matter of any one of Examples 15-17, wherein the read port is configured to receive a read request signal, the write port is configured to receive a write request signal, and the output port is configured to output data from at least one of the memory cells responsive to the read request signal, the memory module configured to write data to at least one of the memory cells responsive to the write request signal.

Example 19 includes the subject matter of Example 18, wherein the read request signal is output on the read request output and includes one of the functional read input and the scrub read input based on the scrub read enable input.

Example 20 includes the subject matter of any one of Examples 18 and 19, wherein the write request signal is output on the write request output and includes one of the functional write input and the scrub write input based on the scrub write enable input.

The terms and expressions which have been employed herein are used as terms of description and not of limitation, and there is no intention, in the use of such terms and expressions, of excluding any equivalents of the features shown and described (or portions thereof), and it is recognized that various modifications are possible within the scope of the claims. Accordingly, the claims are intended to cover all such equivalents. Various features, aspects, and embodiments have been described herein. The features, aspects, and embodiments are susceptible to combination with one another as well as to variation and modification, as will be appreciated in light of this disclosure. The present disclosure should, therefore, be considered to encompass such combinations, variations, and modifications. It is intended that the scope of the present disclosure be limited not by this detailed description, but rather by the claims appended hereto. Future filed applications claiming priority to this application may claim the disclosed subject matter in a different manner and may generally include any set of one or more elements as variously disclosed or otherwise demonstrated herein.

What is claimed is:

1. A memory device comprising:
a random-access memory circuit having a plurality of memory cells, a read port, a write port, and an output port;
a first multiplexer having a functional read input, a scrub read input, a scrub read enable input, and a read request output, the read request output coupled to the read port;
a second multiplexer having a functional write input, a scrub write input, a scrub write enable input, and a write request output, the write request output coupled to the write port; and
a logic circuit configured to scrub, via the scrub write input, at least one of the memory cells based on the scrub read input while the scrub read enable input and/or the scrub write enable input are asserted.

2. The memory device of claim 1, wherein the read port is configured to receive a read request signal, the write port configured to receive a write request signal, and the output port configured to output data from at least one of the memory cells responsive to the read request signal, and wherein the random-access memory circuit is configured to write data to at least one of the memory cells responsive to the write request signal.

3. The memory device of claim 2, wherein the read request signal is output on the read request output and includes one of the functional read input and the scrub read input based on the scrub read enable input.

4. The memory device of claim 2, wherein the write request signal is output on the write request output and includes one of the functional write input and the scrub write input based on the scrub write enable input.

5. The memory device of claim 1, wherein the logic circuit is configured to scrub at least one of the memory cells while a scrub enable signal is asserted.

6. The memory device of claim 5, wherein the logic circuit is configured to read data from at least one of the memory cells based on the scrub read input.

7. The memory device of claim 6, wherein the logic circuit is configured to write data to the at least one of the memory cells based on the scrub write input.

8. The memory device of claim 1, wherein the logic circuit is configured to permit a scrub write to occur based on the scrub write input while the scrub write enable input is asserted.

9. The memory device of claim 1, wherein the logic circuit is configured to permit a scrub read to occur based on the scrub read input while the scrub read enable input is asserted.

10. A method of scrubbing a memory device, the method comprising:
reading data from at least one of a plurality of memory cells of the memory device;
determining that the data is invalid; and
writing, responsive to the determination, corrected data to the at least one of the memory cells while a scrub read enable input signal and/or a scrub write enable input signal are asserted.

11. The method of claim 10, wherein the reading occurs responsive to a scrub read input signal and a scrub enable signal.

12. The method of claim 11, wherein the writing occurs responsive to a scrub write input signal and the scrub enable signal.

13. The method of claim 12, further comprising controlling a first multiplexer based on the scrub read enable input signal, wherein the first multiplexer includes a functional read input configured to receive a functional read input signal, a scrub read input configured to receive the scrub read input signal, a scrub read enable input configured to receive the scrub read enable input signal, and a read request output, the read request output coupled to a read port of the memory device and configured to provide, based on the controlling, one of the functional read input signal and the scrub write input signal to the read port.

14. The method of claim 13, further comprising controlling a second multiplexer based on the scrub write enable input signal, wherein the second multiplexer includes a functional write input configured to receive a functional write input signal, a scrub write input configured to receive the scrub write input signal, a scrub write enable input configured to receive the scrub write enable input signal, and a write request output, the write request output coupled to a write port of the memory and configured to provide, based on the controlling, one of the functional write input signal and the scrub write input signal to the write port.

15. A memory module comprising:
a plurality of memory cells;
a read port;
a write port;
an output port; and
a logic circuit configured to scrub, during a time period when a scrub read enable input and/or a scrub write enable input are asserted, at least one of the memory cells via the read port, the write port, and the output port.

16. The memory module of claim 15, wherein the read port is coupled to a first multiplexer having a functional read input, a scrub read input, the scrub read enable input, and a read request output, the read request output coupled to the read port.

17. The memory module of claim 16, wherein the write port is coupled to a second multiplexer having a functional write input, a scrub write input, the scrub write enable input, and a write request output, the write request output coupled to the write port.

18. The memory module of claim 16, wherein the read port is configured to receive a read request signal, the write port is configured to receive a write request signal, and the output port is configured to output data from at least one of the memory cells responsive to the read request signal, the memory module configured to write data to at least one of the memory cells responsive to the write request signal.

19. The memory module of claim 18, wherein the read request signal is output on the read request output and includes one of the functional read input and the scrub read input based on the scrub read enable input.

20. The memory module of claim 18, wherein the write request signal is output on the write request output and includes one of the functional write input and the scrub write input based on the scrub write enable input.
